(19) United States
(12) Patent Application Publication
(10) Pub. No.: US 2015/0000737 A1
(43) Pub. Date: Jan. 1, 2015

(54) SOLAR CELL AND METHOD OF MANUFACTURING SOLAR CELL

(71) Applicant: SANYO ELECTRIC CO., LTD., Osaka (JP)

(72) Inventors: Yasuto MIYAKE, Osaka (JP); Takahiro MISHIMA, Hyogo (JP)

(21) Appl. No.: 14/485,858

(22) Filed: Sep. 15, 2014

Related U.S. Application Data
(63) Continuation of application No. PCT/JP2013/057795, filed on Mar. 19, 2013.

(30) Foreign Application Priority Data
Mar. 23, 2012 (JP) 2012-067170

(51) Int. Cl. H01L 31/0224; H01L 31/028

(52) U.S. Cl. CPC H01L 31/022425; H01L 31/028
USPC 136/256; 438/98

(57) ABSTRACT

A solar cell includes a photoelectric conversion body and an electrode. One principal surface of the photoelectric conversion body includes a silicon surface made of silicon. The electrode is disposed on the photoelectric conversion body. The electrode includes a tin oxide layer and a metal layer. The tin oxide layer is disposed on the silicon surface. The metal layer is disposed on the tin oxide layer. The tin oxide layer includes a first tin oxide layer and a second tin oxide layer. The second tin oxide layer is stacked on the first tin oxide layer. The oxygen concentration in the second tin oxide layer is lower than that in the first tin oxide layer. At least of one of the surfaces of the tin oxide layer comprises the second tin oxide layer.

### CROSS REFERENCE TO RELATED APPLICATIONS

This application is a continuation application of International Application No. PCT/JP2013/057795, filed on Mar. 19, 2013, entitled “SOLAR CELL AND METHOD OF MANUFACTURING SAME”, which claims priority based on Article 8 of Patent Cooperation Treaty from prior Japanese Patent Applications No. 2012-067170, filed on Mar. 23, 2012, the entire contents of which are incorporated herein by reference.

### BACKGROUND OF THE INVENTION

1. Field of the Invention

This disclosure relates to a solar cell and a method of manufacturing a solar cell.

2. Description of Related Art

Solar cells have drawn increasing attention in recent years as energy sources with small environmental loads. In general, a solar cell includes a photoelectric conversion body and electrodes. Patent Document 1, for example, discloses that an electrode includes a seed layer and contact plating.

Patent Document 1: Published Japanese Translation of PCT

### SUMMARY OF THE INVENTION

In recent years, there has been a growing demand for further improvement to the reliability of solar cells.

An object of an embodiment of the invention is to provide a solar cell with improved reliability.

A solar cell of an aspect of the invention includes a photoelectric conversion body and electrodes. One principal surface of the photoelectric conversion body includes silicon surfaces made of silicon. The electrodes are disposed on the photoelectric conversion body. Electrodes each include a tin oxide layer and a metal layer. The tin oxide layer is disposed on each silicon surface. The metal layer is disposed on the tin oxide layer. The tin oxide layer includes a first tin oxide layer and a second tin oxide layer. The second tin oxide layer is stacked on the first tin oxide layer. The oxygen concentration in the second tin oxide layer is lower than that in the first tin oxide layer. At least one of the layers of the tin oxide layer comprises the second tin oxide layer.

In a method of manufacturing the solar cell of an aspect of the invention, the tin oxide layer and the metal layer are formed in this sequence on the silicon-made silicon surfaces of the photoelectric conversion body, whose one principal surface includes the silicon surfaces. The tin oxide layer and the metal layer are patterned by etching. Thereby, the electrodes each including the patterned tin oxide layer and the patterned metal layer are formed. The tin oxide layer is formed in a way that: the tin oxide layer includes the first tin oxide layer, and the second tin oxide layer which is stacked on the first tin oxide layer, and whose oxygen concentration is lower than that in the first tin oxide layer; and at least one of the surfaces of the tin oxide layer comprises the second tin oxide layer.

The above aspects of the invention can provide a solar cell with improved reliability.

### BRIEF DESCRIPTION OF THE DRAWINGS

FIG. 1 is a schematic rear view of a solar cell of a first embodiment.

FIG. 2 is a schematic cross-sectional view of the solar cell of the first embodiment.

FIG. 3 is a schematic cross-sectional view for explaining a method of manufacturing the solar cell of the first embodiment.

FIG. 4 is a schematic cross-sectional view of a solar cell of Reference Example 2.

FIG. 5 is a schematic cross-sectional view of a solar cell of a second embodiment.

FIG. 6 is a schematic cross-sectional view for explaining a method of manufacturing the solar cell of the second embodiment.

FIG. 7 is a schematic cross-sectional view of a solar cell of a third embodiment.

FIG. 8 is a schematic cross-sectional view for explaining a method of manufacturing the solar cell of the third embodiment.

### DETAILED DESCRIPTION OF EMBODIMENTS

Hereinafter, examples of preferred embodiments carrying out the invention are described. It should be noted that the following embodiments are provided just for illustrative purposes. The invention should not be limited at all to the following embodiments.

In the drawings referred to in the embodiments and other parts, components having substantially the same function are referred to with the same reference numeral. In addition, the drawings referred to in the embodiments and other parts are illustrated schematically, and the dimensional ratio and the like of objects depicted in the drawings are different from those of actual objects in some cases. The dimensional ratio and the like of objects are also different among the drawings in some cases. The specific dimensional ratio and the like of objects should be determined with the following description taken into consideration.

### First Embodiment

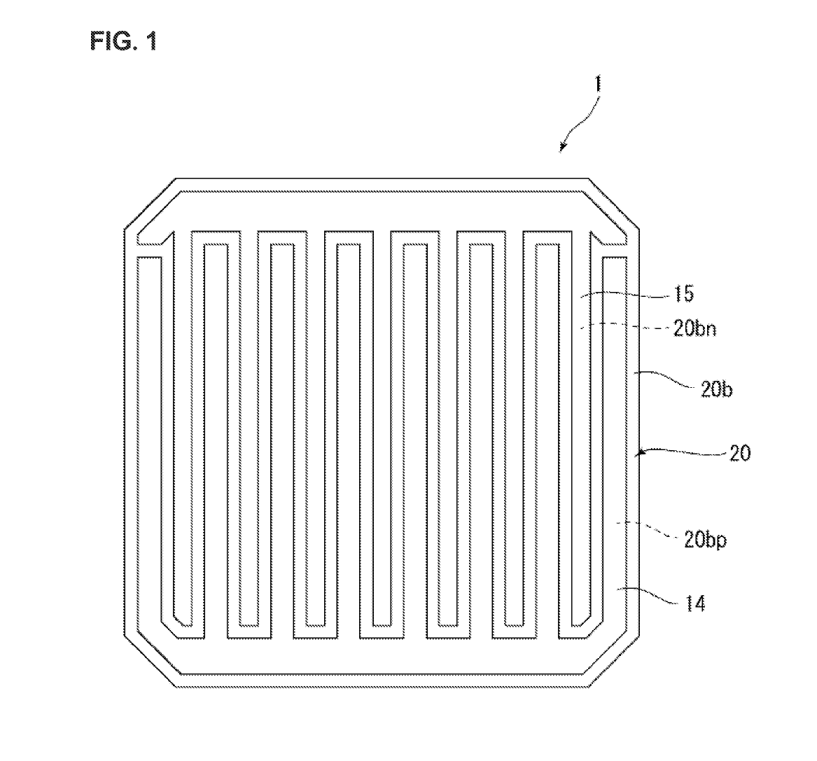

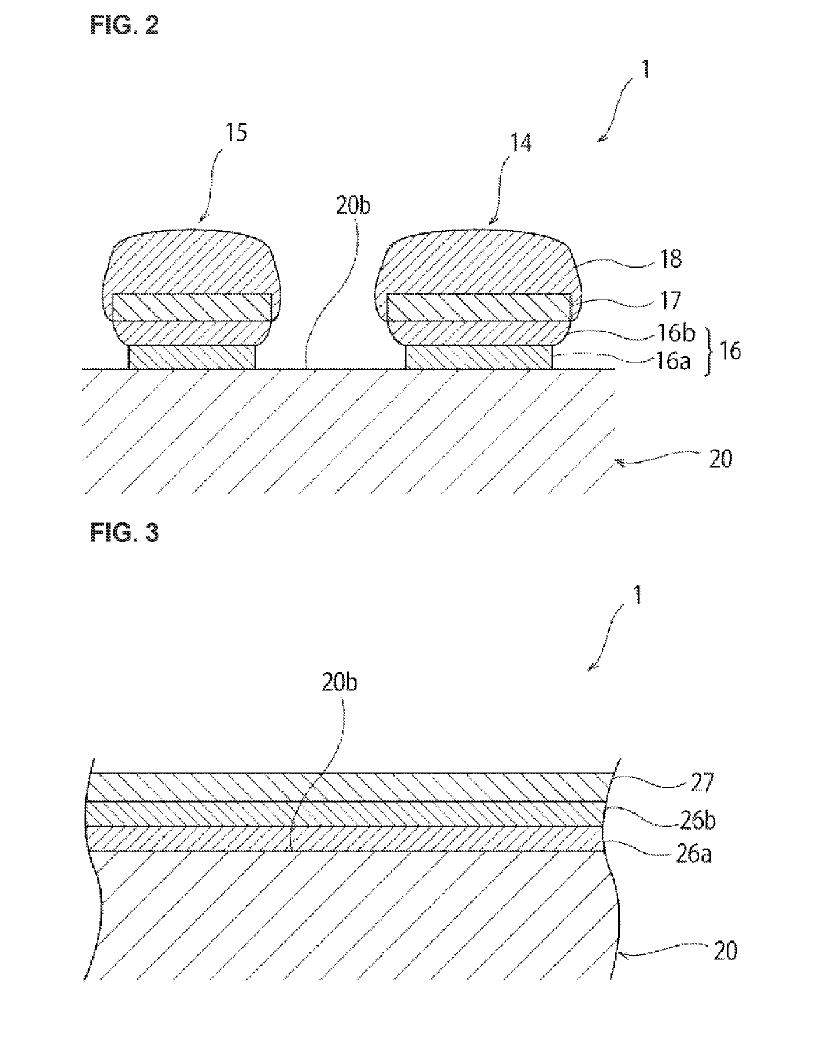

As illustrated in FIGS. 1 and 2, solar cell 1 includes photoelectric conversion body 20. Photoelectric conversion body 20 includes a first principal surface and second principal surface 20b. Of the first principal surface and second principal surface 20b, the first principal surface forms a light-receiving surface, and second principle surface 20b forms a back surface. In this respect, the “light-receiving surface” is a surface exerting a leading role in receiving light.

Photoelectric conversion body 20 is a member configured to generate carries such as holes and electrons upon receipt of light. Photoelectric conversion body 20 may be configured to generate carriers only when receiving light with the first principal surface forming the light-receiving surface. Otherwise, photoelectric conversion body 20 may be configured to generate carriers when receiving light not only with the first principal surface but also with second principal surface 20b forming the back surface.

Photoelectric conversion body 20 has p-type surface 20bp and n-type surface 20bn in second principal surface 20b. Each of p-type surface 20bp and n-type surface 20bn is a silicon surface made of silicon.

P-side electrode 14 is disposed on p-type surface 20bp. N-side electrode 15 is disposed on n-type surface 20bn. Electrodes 14, 15 are each provided in the form of comb teeth. To put it concretely, electrodes 14, 15 each include: finger portions extending in one direction; and a bus bar portion intersecting the finger portions and electrically connecting the finger portions.

Nevertheless, the invention imposes no specific restriction on the configuration of the electrodes. Each electrode may be formed from fingers alone, for example.

Photoelectric conversion body 20 may include: for example, a substrate made of a semiconductor material; a p-type semiconductor layer disposed on one principle surface of the substrate, and forming p-type surface 20bp; and an n-type semiconductor layer disposed on the one principal surface of the substrate, and forming n-type surface 20bn. P-type surface 20bp may be made of a p-type dopant diffused region which is provided in the substrate. N-type surface 20bn may be made of an n-type dopant diffused region which is provided in the substrate.

Each of electrodes 14, 15 includes: tin oxide layer 16 disposed on p-type surface 20bp or n-type surface 20bn; metal layer 17 disposed on tin oxide layer 16; and plated layer 18. Tin oxide layer 16 is disposed directly on p-type surface 20bp or n-type surface 20bn.

Tin oxide layer 16 includes: first tin oxide layer 16a; and second tin oxide layer 16b stacked on first tin oxide layer 16a. At least of one of the surfaces of tin oxide layer 16 comprises second tin oxide layer 16b. To put it concretely, in solar cell 1, a metal layer 17-side surface of tin oxide layer 16 comprises second tin oxide layer 16b. The oxygen concentration in second tin oxide layer 16b is lower than that in first tin oxide layer 16a. It is desirable that the thickness of tin oxide layer 16a be thinner than that of tin oxide layer 16b.

Metal layer 17 is disposed directly on tin oxide layer 16. It is desirable that metal layer 17 include Cu. To put it concretely, it is desirable that metal layer 17 be made of Cu, Ti, Al, Ag, Ni, or an alloy including at least two of them.

Plated layer 18 is disposed on metal layer 17. To put it concretely, plated layer 18 is disposed covering the top and side surfaces of metal layer 17. Plated layer 18 is a layer formed by plating such as electroplating. No specific restriction is imposed on the constituent materials of plated layer 18. Plated layer 18 may be made of Cu, a Cu-containing alloy, Si, Ni, Ag or the like.

Next, descriptions are provided for an example of a method of manufacturing solar cell 1.

First of all, photoelectric conversion body 20 is prepared. Thereafter, as illustrated in FIG. 3, first tin oxide film 26a for forming first tin oxide layer 16a, second tin oxide film 26b for forming second tin oxide layer 16b, and metal film 27 for forming metal layer 17 are formed in this sequence substantially on the entire surface of second principal surface 20b of photoelectric conversion body 20.

For example, a tin oxide film with a predetermined oxide concentration is formed on second principal surface 20b of photoelectric conversion body 20. Thereafter, a top surface-side portion of the tin oxide film is subjected to a reduction treatment, and the oxygen concentration in the top surface-side portion is reduced. Thus, first and second tin oxide films 26a, 26b are formed. Subsequently, metal film 27 is formed on second tin oxide film 26b. As for the reduction treatment, it is possible to select any one of a method of sputtering the top surface of the tin oxide film with a target containing elements causing a reduction action, a method of irradiating the top surface of the tin oxide film with hydrogen plasma; and soaking the top surface of the tin oxide film in a liquid causing a reduction action, for example. The tin oxide film and the metal film may be formed by sputtering, CVD (Chemical Vapor Deposition) or the like.

The method of forming first and second tin oxide films 26a, 26b as well as metal layer 17 is not limited to those mentioned above. For example, first and second tin oxide films 26a, 26b and metal layer 17 may be formed by: forming first and second tin oxide films 26a, 26b under different film-forming conditions such as amounts of gases to be added, for example; and thereafter forming metal layer 17.

Subsequently, first and second tin oxide films 26a, 26b and metal film 27 are patterned by etching. Thereby, patterned first and second tin oxide layers 16a, 16b and patterned metal layer 17 are formed. Concrete examples of an etchant preferably used to etch first and second tin oxide films 26a, 26b and metal film 27 include hydrochloric acid, oxalic acid, aqua regia, and a liquid mixture of hydrochloric acid and ferric chloride or the like.

Thereafter, power is supplied to first and second tin oxide layers 16a, 16b and metal layer 17 by using first and second tin oxide layers 16a, 16b and metal layer 17 as seed layers. Thereby, plated layer 18 is formed. By this, electrodes 14, 15 each including first and second tin oxide layers 16a, 16b, metal layer 17 and plated layer 18 are formed, and solar cell 1 is completed. It is more preferable that plated layer 18 be formed by electroplating, for example.

For example, if the tin oxide film comprises a single tin oxide layer whose oxygen concentration is higher and virtually even across the layer, only the tin oxide layer is apt to be selectively etched in a traverse direction from its sides while the patterning is carried out by etching the tin oxide layer and the metal layer. This makes the tin oxide layer more likely to come off the silicon surfaces, and the tin oxide layer and the metal layer are more likely to separate from each other. This may lead to cases such as deterioration in the reliability of the manufactured solar cell, and a decrease in the photoelectric conversion efficiency of the solar cell.

In solar cell 1 of the embodiment, however, the metal layer 17-side surface of tin oxide layer 16 comprises hard-to-etch second tin oxide layer 16b whose oxygen concentration is lower. This makes it possible to prevent the metal layer 17-side surface of tin oxide layer 16 from being etched to a large extent, and to inhibit a decrease in the bonding strength between tin oxide layer 16 and metal layer 17.

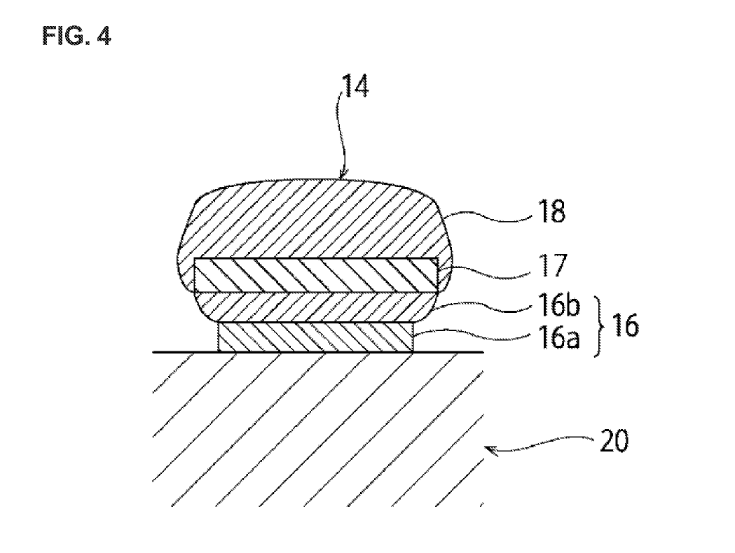

To put it concretely, as illustrated in FIG. 4, first and second tin oxide layers 16a, 16b in the embodiment differ from each other in terms of the length (hereinafter referred to as a “width”) in a direction perpendicular to the longitudinal direction of electrodes 14, 15. The width of second tin oxide layer 16b closer to metal layer 17 is greater than that of first tin oxide layer 16a closer to photoelectric conversion body 20. This increases the contact area between the lower surface of metal layer 17 and the upper surface of tin oxide layer 16 in comparison with the case where the single tin oxide layer whose oxygen concentration is higher and virtually even across the layer is used, and increases the bonding strength in the interface between metal layer 17 and tin oxide layer 16. Accordingly, it is possible to manufacture the solar cell with improved reliability, and with improved photoelectric conversion efficiency.

Meanwhile, from a viewpoint of improvement in the bonding strength between the tin oxide layer and the metal layer, a conceivable option is a reduction in the oxygen concentration in the entire tin oxide layer. In this case, however, electric resistance becomes higher in the tin oxide layer. This may lead to a case where the photoelectric conversion efficiency of the obtained solar cell becomes lower.

In contrast to this, in solar cell 1, tin oxide layer 16 includes second tin oxide layer 16b whose oxygen concentration is lower, and first tin oxide layer 16a whose oxygen concentration is higher. This inhibits the increase in the electric resistance of tin oxide layer 16. Accordingly, it is possible to inhibit the decrease in the photoelectric conversion efficiency.

Descriptions are hereinbelow provided for other examples of the preferable embodiment of the invention. In the following descriptions, members having virtually the same functions as those of the first embodiment are denoted by the same reference signs, and explanations for such members are omitted.

### Second and Third Embodiments

The first embodiment describes the example where only the metal layer 17-side surface of tin oxide layer 16 comprises second oxide layer 16b whose oxygen concentration is lower. The invention, however, is not limited to this.

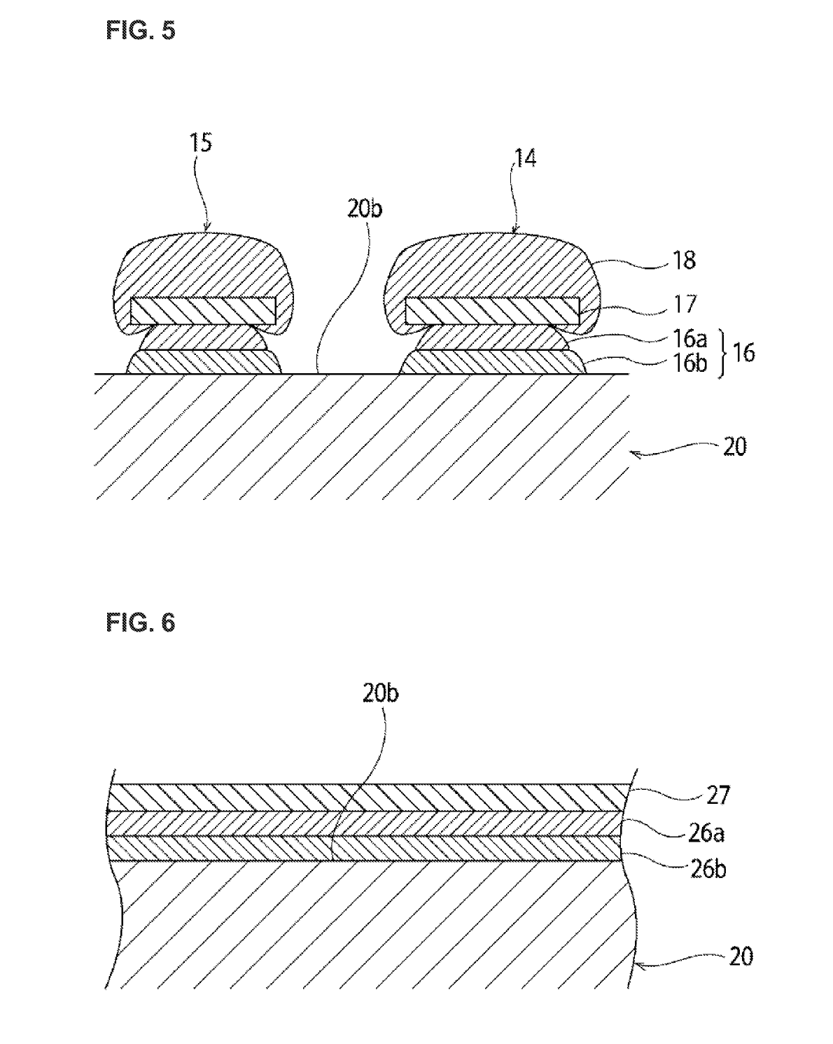

For example, as illustrated in FIG. 5, only the photoelectric conversion body 20-side surface of tin oxide layer 16 may be formed from second tin oxide layer 16b whose oxygen concentration is lower. In other words, second tin oxide layer 16b and first tin oxide layer 16a may be stacked in this sequence on photoelectric conversion body 20. In this case, it is desirable that the width of first tin oxide layer 16a become gradually narrower from second tin oxide layer 16b toward metal layer 17 in the thickness direction of first tin oxide layer 16a. Thereby, plated layer 18 is formed covering the top and side surfaces of metal layer 17, and additionally lower surface portions of metal layer 17 which are exposed from first tin oxide film 16a. As a result, it is possible to increase the contact area between metal layer 17 and plated layer 18, and to decrease the contact resistance between metal layer 17 and plated layer 18.

In this case, as illustrated in FIG. 6, first tin oxide film 26a may be formed after second tin oxide film 26b is formed. A method of changing the width of first tin oxide layer 16a can be realized, for example, by gradually changing the amount of an oxygen gas to be added. It should be noted that the width of first tin oxide layer 16a may be even in the thickness direction of the layer.

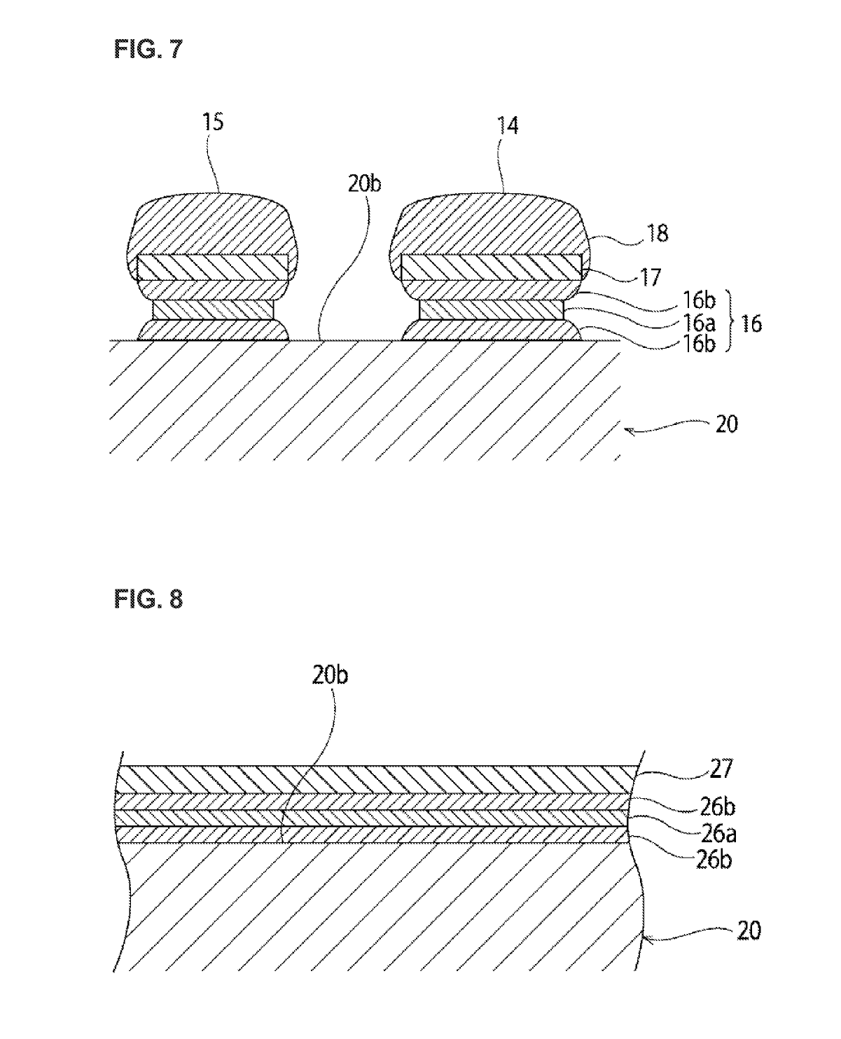

For example, as illustrated in FIG. 7, both the metal layer 17-side surface and the photoelectric conversion body 20-side surface of tin oxide layer 16 may be formed from second tin oxide layer 16b whose oxygen concentration is lower. In other words, second tin oxide layer 16b, first tin oxide layer 16a and second tin oxide layer 16b may be stacked in this sequence on photoelectric conversion body 20. The width of first tin oxide layer 16a is narrower than that of second tin oxide layer 16b closer to metal layer 17 and that of second tin oxide layer 16b closer to photoelectric conversion body 20. This makes tin oxide layer 16 capable of inhibiting the increase in the electric resistance while maintaining the boding strength between second tin oxide layer 16b and metal layer 17, and between second tin oxide layer 16b and photoelectric conversion body 20. Accordingly, it is possible to inhibit the decrease in the photoelectric conversion efficiency.

In this case, as illustrated in FIG. 8, second tin oxide film 26b may be formed first, then first tin oxide film 26a may be formed, and second tin oxide film 26b may be formed again.

Meanwhile, the oxygen concentration in first tin oxide layer 16 may gradually change along with the thickness direction of tin oxide layer 16, and one surface of tin oxide layer 16 may be provided with a part whose oxygen concentration is lower.

1. A solar cell comprising:
a photoelectric conversion body whose one principal surface includes a silicon surface made of silicon; and
an electrode disposed on the photoelectric conversion body, wherein
the electrode includes a tin oxide layer disposed on the silicon surface, and a metal layer disposed on the tin oxide layer,
the tin oxide layer includes a first tin oxide layer, and a second tin oxide layer which is stacked on the first tin oxide layer, and whose oxygen concentration is lower than that in the first tin oxide layer, and
at least one surface of the tin oxide layer comprises the second tin oxide layer.

2. The solar cell according to claim 1, wherein a metal layer-side surface of the tin oxide layer comprises the second tin oxide layer.

3. The solar cell according to claim 1, wherein a silicon surface-side surface of the tin oxide layer comprises the second tin oxide layer.

4. The solar cell according to claim 1, wherein a thickness of the second tin oxide layer is smaller than that of the first tin oxide layer.

5. The solar cell according to claim 1, wherein the metal layer includes Cu.

6. A method of manufacturing a solar cell, comprising:
forming a tin oxide layer and a metal layer in this sequence on a silicon surface of a photoelectric conversion body which is one principal surface comprising silicon; and
patterning the tin oxide layer and the metal layer by etching, and thereby forming an electrode which includes the patterned tin oxide layer and the patterned metal layer, wherein
the tin oxide layer is formed such that the tin oxide layer includes a first tin oxide layer, and a second tin oxide layer which is stacked on the first tin oxide layer, and whose oxygen concentration is lower than that in the first tin oxide layer, and at least one surface of the tin oxide layer comprises the second tin oxide layer.

7. The method of manufacturing a solar cell according to claim 6, wherein the tin oxide layer and the metal layer are etched by use of any one of hydrochloric acid, oxalic acid, aqua regia, and a liquid mixture of hydrochloric acid and ferric chloride.

8. The solar cell according to claim 2, wherein the width of the second tin oxide layer is greater than that of the first tin oxide layer.

9. The solar cell according to claim 3, wherein the width of the first tin oxide layer become narrower from the second tin oxide layer toward the metal layer in the thickness direction of the first tin oxide layer.
